(19) United States
(12) Patent Application Publication
(10) Pub. No.: US 2001/0005150 A1
(43) Pub. Date: Jun. 28, 2001

(54) Latch type sense amplifier and method for operating thereof

(76) Inventor: In Hwan Eum, Kyoungki-do (KR)

Correspondence Address: Pillsbury Madison & Sutro LLP, Intellectual Property Group, Ninth Floor, East Tower, 1100 New York Avenue, N.W., Washington, DC, 20005-3918, US

(21) Appl. No.: 09/745,428

(22) Filed: Dec. 26, 2000

(30) Foreign Application Priority Data
Dec. 24, 1999 (KR) 1999-61714

(51) Int. Cl. H03F 3/45

(52) U.S. Cl. 327/55

(57) ABSTRACT

This invention features, in part, a latch type sense amplifier which can prevent a mis-operation and increase operation speed by performing a sensing operation twice in one read cycle. There is also provided a method for operating a sense amplifier. The method for operating the latch type sense amplifier includes: 1) electrically separating a first node and a second node of the sense amplifier having a sensing potential from output terminals, respectively, during an initial operation and a standby operation when the sense amplifier is not operated, and equalizing a potential of the first node and a potential of the second node; 2) first sensing a data of a bit line according to a sense amplifier enable signal; 3) maintaining the sensed data by respectively separating the first node and the second node from the output terminals, and 4) equalizing the potential of the first node and the potential of the second node; and 5) electrically separating the first node from the second node, connecting the first node and the second node respectively to the output terminals, and second sensing the data of the bit line.

### BACKGROUND

1. Field of the Invention

The present invention relates to a latch type sense amplifier for use with a semiconductor memory device. It also relates to a method for operating a sense amplifier. More specifically, the inventions claimed herein feature an improved latch type sense amplifier arrangement which can prevent a mis-operation and increase operational speed by performing a sensing operation twice in one read cycle.

2. General Background and Related Art

In general, when weak data signals stored in a cell array are applied to a bit line and a bit bar line (or a data line and a data bar line), a sense amplifier senses and amplifies the data signals, and transmits them to a data output buffer. The sense amplifier is designed to precisely sense a small potential difference of a signal representing data from a cell, amplify the data signal during a short time period, and transmit the amplified signal to a succeeding circuit.

The read operation for reading data stored in a semiconductor device memory cell will now be explained. When a memory cell having a particular row address is to be read, a word line corresponding to the address is enabled. After a predetermined time (row active time (tRCD)), a bit line sense amplifier is operated, for latching the cell data of the enabled word line. Thereafter, when a column address is specified, selected information of the bit line sense amplifier is transmitted to a data line sense amplifier through a data line, amplified in the data line sense amplifier and transmitted to the data output buffer.

The operation and constitution of a conventional sense amplifier will now be described with reference to the accompanying drawings.

FIG. 1 (Prior Art) is a circuit diagram illustrating a conventional cross-coupled latch type sense amplifier. The sense amplifier includes a first inverter having a PMOS transistor P1 and an NMOS transistor N1 for outputting a high or low signal to an output node Nd1 according to a signal sa1o of an output node Nd2. A second inverter is constituted by a PMOS transistor P2 and an NMOS transistor N2 for outputting a high or low signal to an output node Nd2 according to a signal sa1ob of the output node Nd1. An NMOS transistor N5 forms a current path between each inverter and a ground voltage Vss according to a sense amplifier enable signal pse1. An NMOS transistor N3 connected between the NMOS transistor N1 and the NMOS transistor N5, receives an input signal sai through its gate. An NMOS transistor N5 connected between the NMOS transistor N2 and the NMOS transistor N5, receives an input signal saib through its gate.

The conventional latch type sense amplifier begins operation starts to operate when the NMOS transistor N5 which functions as a current source turns on during a high period of the sense amplifier enable signal pse1. Thereafter, when the data sai and saib of the bit line having a minute voltage difference are inputted to the NMOS transistors N3 and N4, respectively, the sense amplifier differentially amplifies the data sai and saib, and outputs the amplified signals sa1ob and sa1o to the output nodes Nd1 and Nd2.

However, once the sense amplifier senses an error data when enabled, even if a correct data is applied to the bit line afterward, the sensed error data is not restored. In order to prevent such a mis-operation, the operation of the sense amplifier is controlled until the correct data is inputted. Therefore, the sense amplifier has a disadvantage in that its operation speed is lowered.

FIGS. 2A through 2D (all Prior Art) are waveform diagrams that help to explain the operation of the conventional latch type sense amplifier. The sensing operation is normally performed in operation voltages of 2V (FIG. 2A), 3V (FIG. 2B), 5V (FIG. 2C) and 7V (FIG. 2D), but the inverted bit line data cannot be re-sensed.

FIG. 3 (Prior Art) is a circuit diagram illustrating a sense amplifier having current mirrors type structure. The sense amplifier includes first and second sense amplifier units 20 and 22 having a current mirror type structure, for sensing and amplifying the weak data signals sai and saib from the memory cell during an enable operation. A third sense amplifier unit 24 of the current mirror type structure, receives output signals sa2o and sa2ob from the first and second sense amplifier units 20, 22, and outputs a differentially-amplified signal sa22o.

When the sense amplifier enable signals pse1 and pse2 of a high level are applied, NMOS transistors N8 and N11 operated as a current source for the first and second sense amplifier units 20 and 22 are turned on, the first and second sense amplifier units 20 and 22 are operated. The first and second sense amplifier units 20 and 22 respectively output the signals sa2o and sa2ob obtained by sensing and amplifying the weak data signals (sai and saib), (saob and sao) from the memory cell to the third sense amplifier unit 24 through nodes Nd5 and Nd8. The third sense amplifier unit 24 receives the output signals sa2o and sa2ob amplified in the first and second sense amplifier units 20 and 22, and outputs a re-amplified signal sa22o through a node Nd11.

As a result, this conventional sense amplifier having the current mirror type structure as shown in FIG. 3 (Prior Art) differentially amplifies swing values of the bit lines by the first and second sense amplifier units 20 and 22 at a first terminal, and differentially amplifies them again by the third sense amplifier unit 24 at a second terminal, thereby outputting the signal sa22o.

However, the sense amplifier cannot be operated until a voltage of the bit line BL and a voltage of the bit bar line /BL have a potential difference over about 100 mV. This causes operation speed to be reduced. When the potential difference is not over 100 mV, if an opposite signal voltage is applied to the bit line due to noise, the current mirror type output voltage amplifies the opposite signal, which results in the mis-operation.

When a pair of bit lines perform a swing operation with a small voltage difference (37 mV) near a power supply voltage, and operate the sense amplifier at a low voltage (1.3 V), the first and second sense amplifier units 20, 22 at the first terminal do not generate a sufficient voltage gain after sensing an input voltage difference, and transmit the data signal to the third sense amplifier unit 24. Here, the potential level of the data signal from the sense amplifier units 20 and 22 at the first terminal is low, and thus the third sense amplifier unit 24 at the second terminal is not sufficiently driven, thereby causing the mis-operation or reducing the operation speed.

FIGS. 4A through 4D (all Prior Art) are waveform diagrams explaining the operation of the conventional current mirror type sense amplifier. The inverted bit line data cannot be sensed at 2V (FIG. 4A). In addition, although the inversed bit line data is sensed at 3V (FIG. 4B), 5V (FIG. 4C) and 7V (FIG. 4D), the speed is very low.

As described above, once the conventional latch type sense amplifier senses an error data when enabled, even if a correct data is applied to the bit line afterward, the sense amplifier is not restored. Accordingly, the operation of the sense amplifier is controlled until the correct data is inputted to the bit line, thereby lowering the operation speed. In addition, the conventional current mirror type sense amplifier is operated when the bit line and the bit bar line have a predetermined potential difference, thereby lowering the operation speed.

### SUMMARY

The claimed inventions feature a latch type sense amplifier which can prevent a mis-operation and improve an operation speed by performing a sensing operation twice in one read cycle. Also claimed are methods for operating a latch type sense amplifier.

One claimed method of operation includes:

electrically separating a first node and a second node of the sense amplifier having a sensing potential from output terminals, respectively, during an initial operation and a standby operation when the sense amplifier is not operated, and equalizing a potential of the first node and a potential of the second node;

first sensing a data of a bit line according to a sense amplifier enable signal;

maintaining the sensed data by respectively electrically separating the first node and the second node from the output terminals, and equalizing the potential of the first node and the potential of the second node; and

electrically separating the first node from the second node, connecting the first node and the second node respectively to the output terminals, and second sensing the data of the bit line.

Some of the claimed inventions feature a latch type sense amplifier including:

a first inverter unit for outputting an amplified data signal to a first sensing node according to a signal of a second sensing node;

a second inverter unit for outputting the amplified data signal to the second sensing node according to a signal from the first sensing node;

a current source unit for forming a current path to a ground voltage according to a sense amplifier enable signal;

a signal sensing unit having of a first input terminal connected between the first inverter unit and the current source unit, for receiving a first data signal through its gate, and a second input terminal connected between the second inverter unit and the current source unit, for receiving a second data signal through its gate;

an equalization circuit unit for equalizing a potential of the first sensing node and a potential of the second sensing node according to a first control signal notifying an initial operation and a standby operation of the sense amplifier; and

first and second switching units for respectively switching the first sensing node and the first output terminal, and the second sensing node and the second output terminal according to a second control signal.

According to one aspect of the present invention, the first and second input terminals are constituted by NMOS transistors, respectively.

According to another aspect of the present invention, the first and second inverter units are constituted by a PMOS transistor and an NMOS transistor, respectively.

According to still another aspect of the present invention, the current source unit is constituted by an NMOS transistor.

According to still another aspect of the present invention, the first and second switching units are constituted by respective transmission gates.

According to still another aspect of the present invention, the transmission gates are constituted by PMOS and NMOS transistors.

According to still another aspect of the present invention, the equalization circuit unit is constituted by a transmission gate.

According to still another aspect of the present invention, the transmission gates are constituted by PMOS and NMOS transistors.

### BRIEF DESCRIPTION OF THE DRAWINGS

Exemplary embodiments of the inventions will be explained with reference to the accompanying drawings which are given only by way of illustration and thus are not limitative of the present invention, wherein:

FIG. 1 is a circuit diagram illustrating a conventional latch type sense amplifier;

FIGS. 2A through 2D are waveform diagrams explaining the operation of the conventional latch type sense amplifier;

FIG. 3 is a circuit diagram illustrating a conventional current mirror type sense amplifier;

FIGS. 4A through 4D are waveform diagrams explaining the operation of the conventional current mirror type sense amplifier;

FIG. 5 is a circuit diagram illustrating a latch type sense amplifier in accordance with the present invention; and

FIGS. 6A through 6D are waveform diagrams explaining the operation of the latch type sense amplifier in accordance with the present invention.

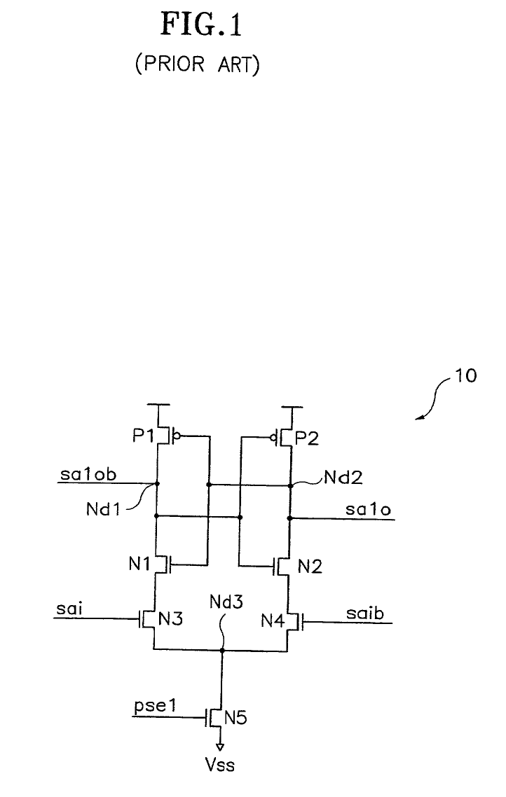

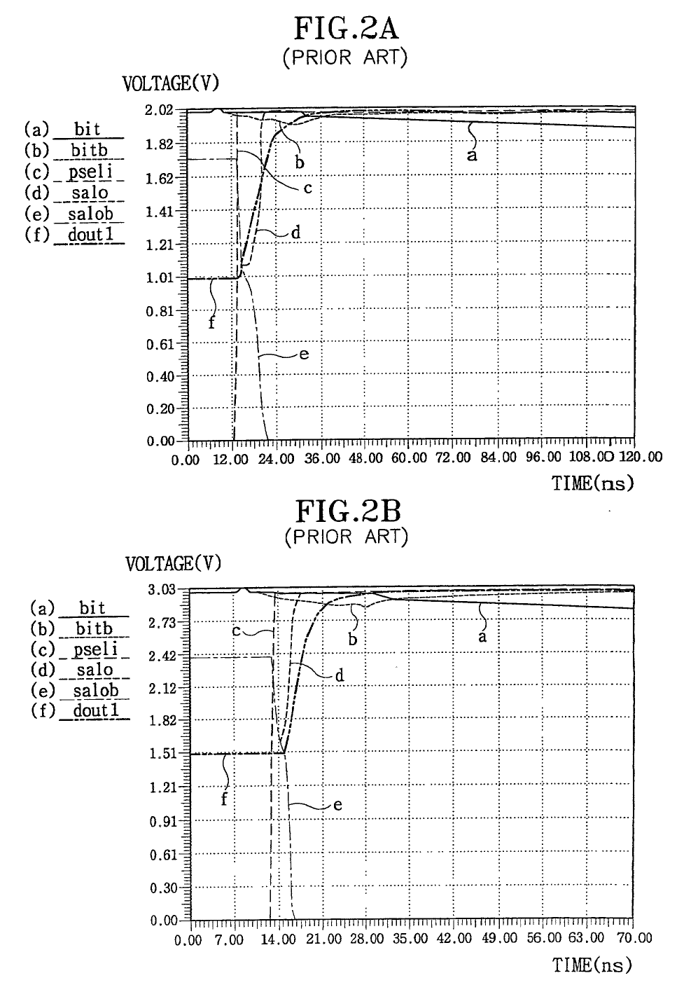

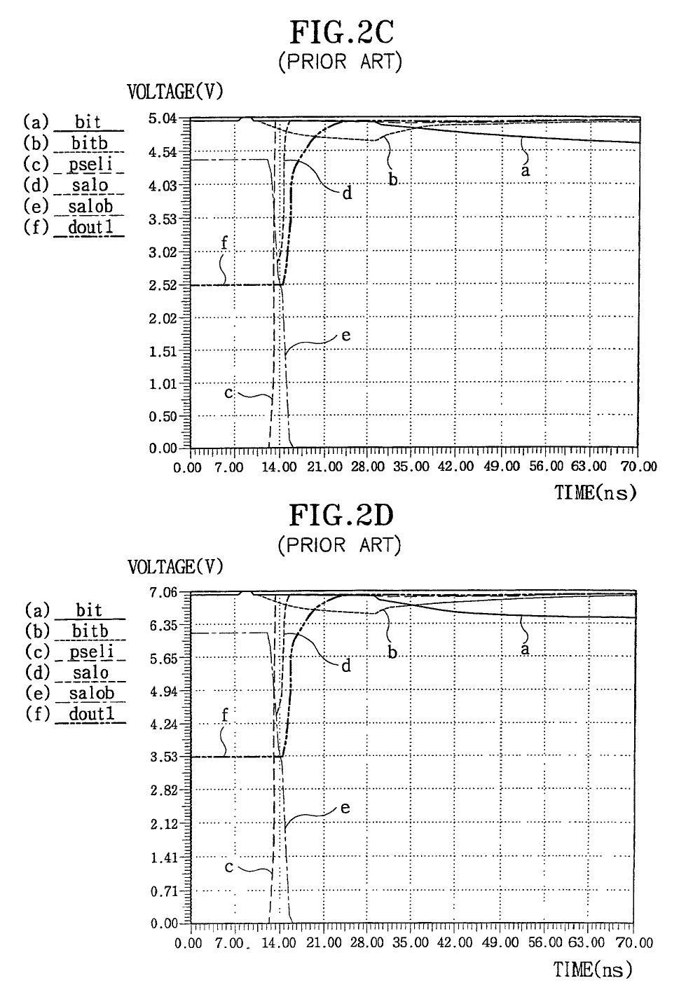

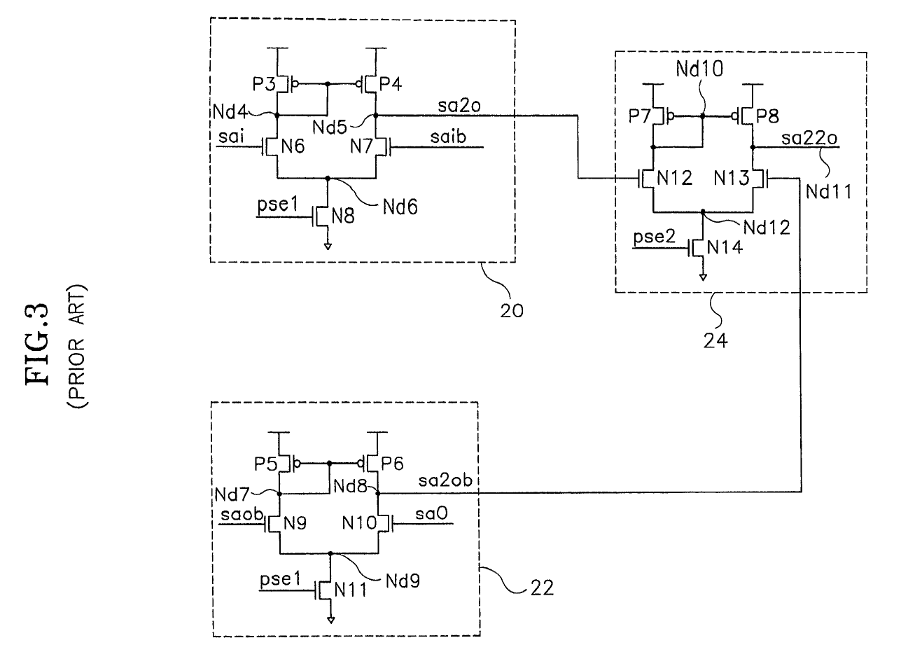

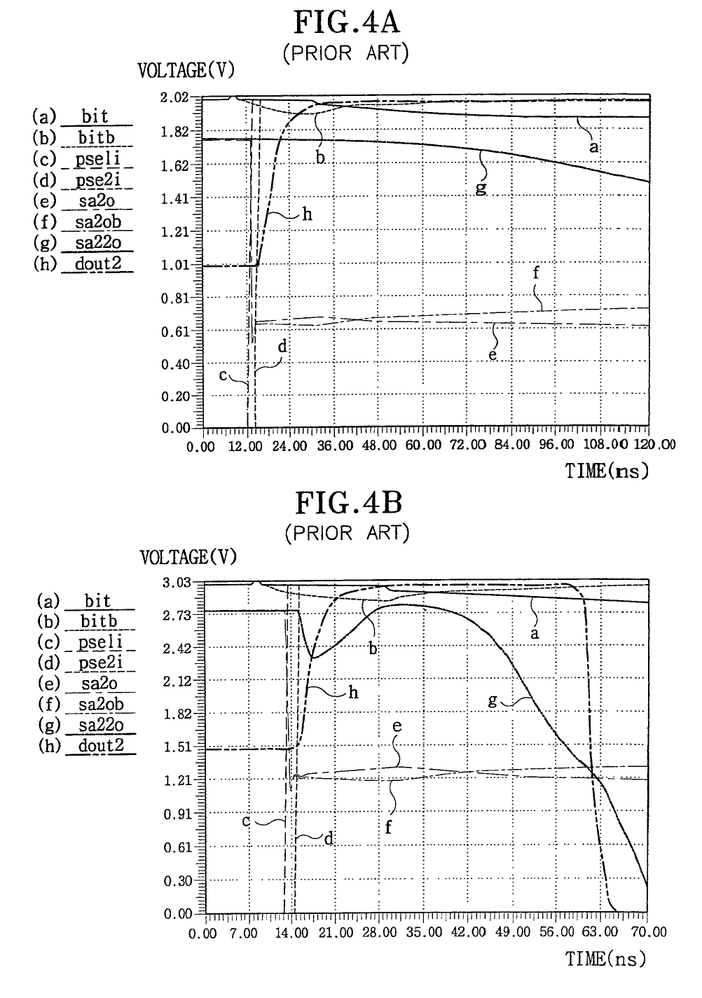

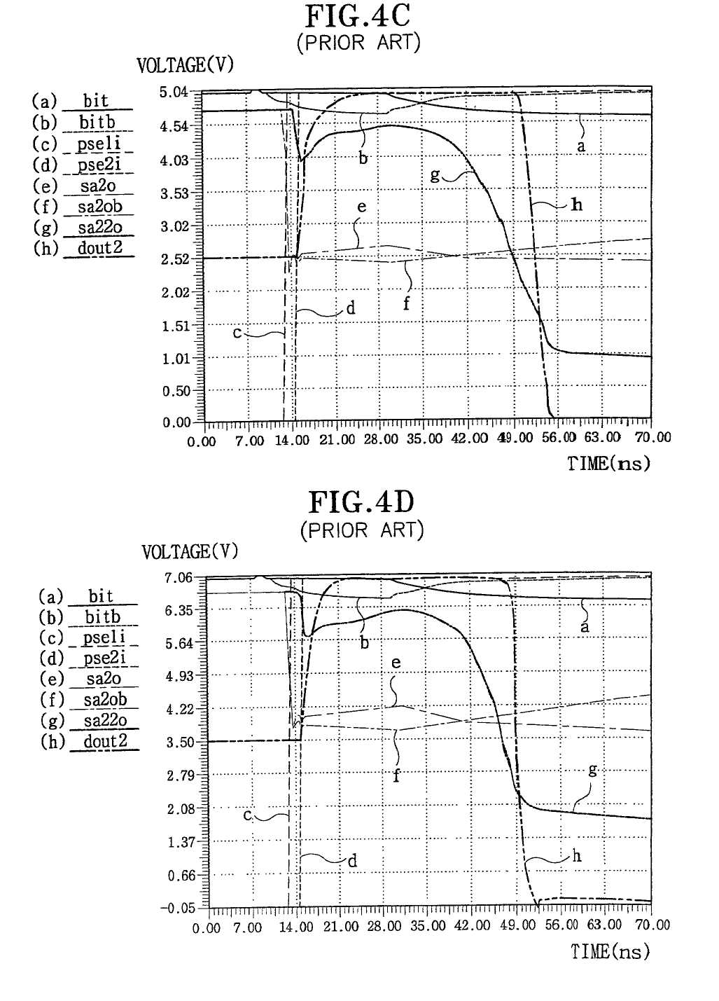

### DETAILED DESCRIPTION

An example of a latch type sense amplifier and a method for operating such a sense amplifier, according to the inventions described and claimed herein, will now be described in detail with reference to the accompanying drawings. In the drawings, elements having an identical function are provided with the identical reference numeral, and repeated explanations thereof will be omitted.

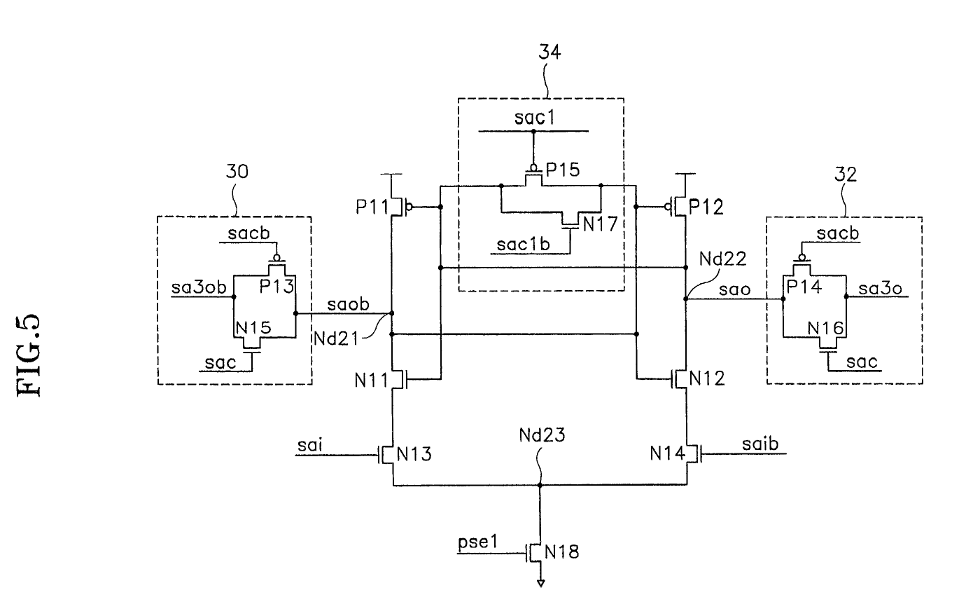

FIG. 5 is a circuit diagram illustrating a latch type sense amplifier in accordance with the present invention. A first inverter, constituted by a PMOS transistor P11 and an NMOS transistor N11, outputs a high or low signal to an output node Nd21 according to a signal sao at an output node Nd22. A second inverter constituted by a PMOS transistor P12 and an NMOS transistor N12, outputs a high or low signal to the output node Nd22 according to a signal saob at the output node Nd21. An NMOS transistor N18 forms a current path to a ground voltage Vss according to a sense amplifier enable signal pse1. An NMOS transistor N13 connected between the NMOS transistor N11 and the NMOS transistor N18, receives an input signal sai through its gate. An NMOS transistor N14 connected between the NMOS transistor N12 and the NMOS transistor N18, receives an input signal saib through its gate. An equalization circuit unit 34 constituted by a PMOS transistor P15 and an NMOS transistor N17 equalizes the output node Nd21 and the output node nd22 according to control signals sad and sac1b notifying an initial operation and a standby operation of the sense amplifier. A first output terminal switching circuit unit 30 constituted by a PMOS transistor P13 and an NMOS transistor N15 switches the output node Nd21 and the output terminal sa3ob according to sense amplifier output control signals sacb and sac. A second output terminal switching circuit unit 32 constituted by a PMOS transistor P14 and an NMOS transistor N16 switches the output node Nd22 and the output terminal sa3o according to the sense amplifier output control signals sacb, sac.

In the initial operation of the sense amplifier, the control signals sac and sac1 are enabled to turn on the equalization circuit unit 34, and thus the signals from the output nodes Nd21 and Nd22 are equalized. Here, the sense amplifier enable signal pse1 is disabled, and thus the sense amplifier is not operated. Thereafter, when a word line WL is enabled and the cell data is transmitted to the bit lines BL and /BL, the sense amplifier enable signal pse1 is enabled, thereby performing a sensing operation. Here, if the firstly-sensed data is a correct data, a high speed can be achieved.

Even if the sensing operation is performed in a latter period of the read cycle, namely a current time, the latch type sense amplifier corrects an error data by re-performing the sensing operation in a time satisfying a speed property. This operation will now be described.

In the first sensing operation, the output nodes Nd21 and Nd22 are connected to the output terminals sa3ob and sa3o by enabling the sense amplifier output control signals sac and sac1. Thereafter, when the word line is enabled and the bit line data have a potential difference between 20 mV and 30 mV, the sense amplifier enable signal pse1 is enabled and the data of the bit line is firstly sensed.

In the second sensing operation, the output nodes Nd21 and Nd22 are disconnected from the output terminals sa3ob and sa3o by disabling the sense amplifier output control signal sac, thereby maintaining the previously-sensed data. Thereafter, when the control signals sad and sac1b are enabled, the output nodes Nd21 and Nd22 are equalized, and thus the sense amplifier can receive a data again. When the control signals sad and sac1b are disabled, the current data of the bit line to be inputted to the gates of the NMOS transistors N13 and N14 are sensed. When the output nodes Nd21 and Nd22 are connected to the output terminals sa3ob and sa3o by enabling the sense amplifier output control signal sac, the current sense amplifier output is transmitted to an output buffer, thereby correcting the error data.

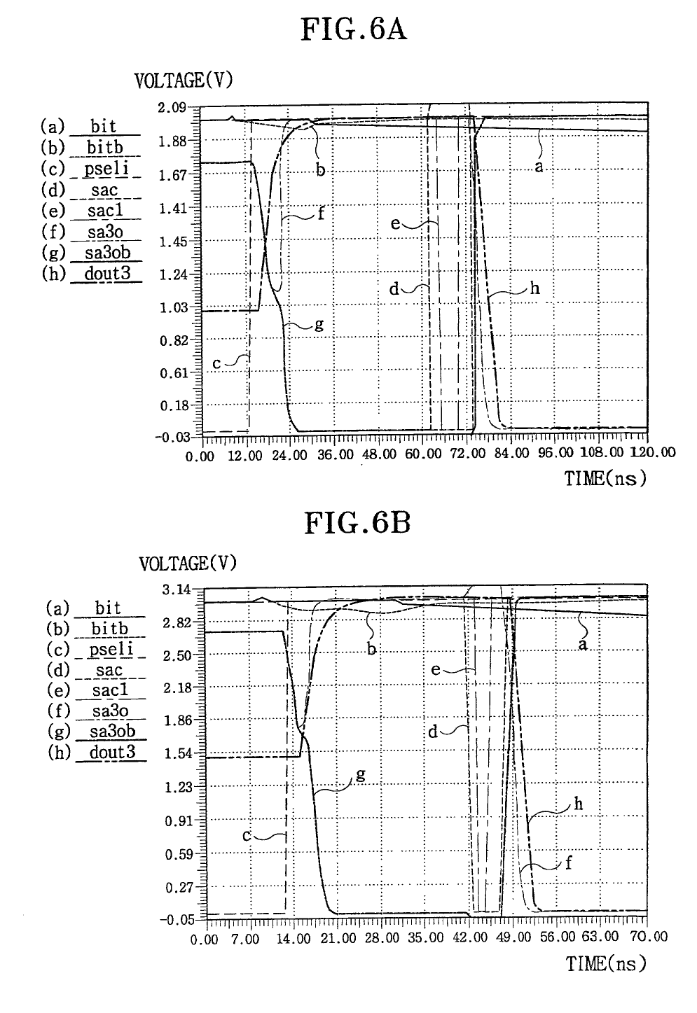

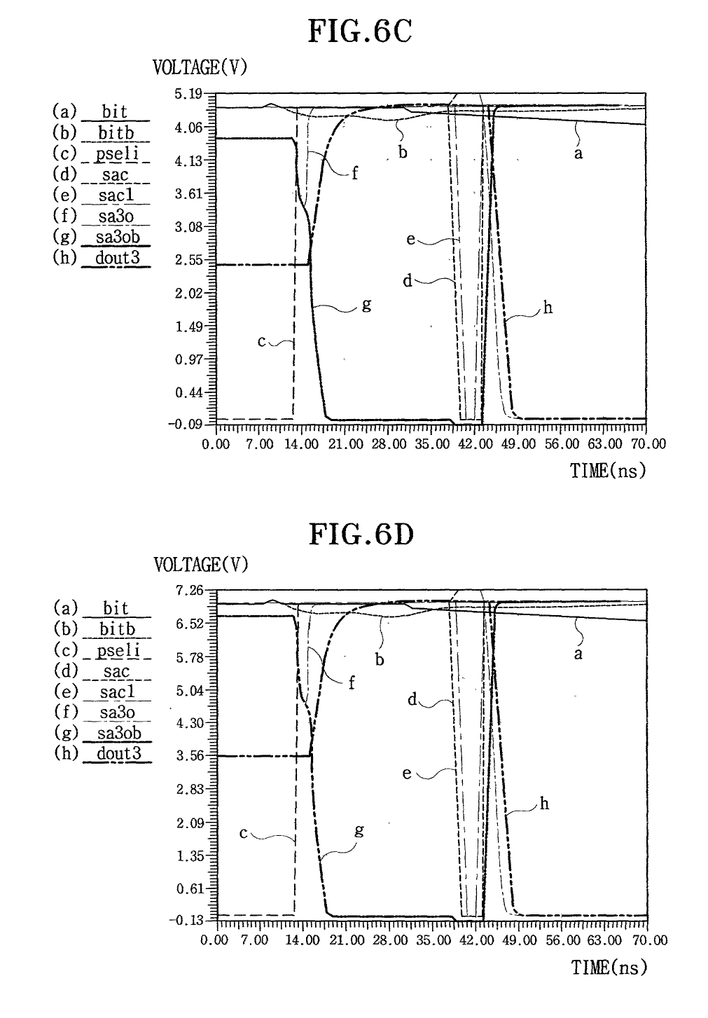

FIGS. 6A through 6D are waveform diagrams of the latch type sense amplifier in accordance with the present invention. As depicted therein, the sensing operation is normally performed in all operation voltages. In addition, after the inversion of the bit line, the output of the sense amplifier and the data correction of the output buffer are rapidly performed according to the second sensing operation.

Since the inversion of the bit line generally occurs in the initial enable period of the word line, if the data is secondly sensed at a last time guaranteeing a read speed property margin, a memory device can be designed to be stably operated without a speed delay. Moreover, in the case that the data inversion is not generated in all cells due to stable operation conditions and internal timing, the memory device having a higher speed can be fabricated.

As discussed earlier, in accordance with the present invention, the memory device stably operated at a high speed in a low power and voltage environment can be designed by using the sense amplifier having excellent sensing ability in high an low voltages, and performing the sensing operation with a small input difference.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefor all changes and modifications that fall within the meets and bounds of the claims, or equivalences of such meets and bounds are therefore intended to be embraced by the appended claims.

What is claimed is:

1. A method for operating a latch type sense amplifier, comprising:
electrically separating a first node and a second node of the sense amplifier having a sensing potential from output terminals, respectively, during an initial operation and a standby operation when the sense amplifier is not operated, and equalizing a potential of the first node and a potential of the second node;
first sensing a data of a bit line according to a sense amplifier enable signal;
maintaining the sensed data by respectively electrically separating the first node and the second node from the output terminals, and equalizing the potential of the first node and the potential of the second node; and
electrically separating the first node from the second node, connecting the first node and the second node respectively to the output terminals, and second sensing the data of the bit line.

2. A latch type sense amplifier comprising:
a first inverter unit for outputting an amplified data signal to a first sensing node according to a signal of a second sensing node;
a second inverter unit for outputting the amplified data signal to the second sensing node according to a signal from the first sensing node;
a current source unit for forming a current path to a ground voltage according to a sense amplifier enable signal;
a signal sensing unit including a first input terminal connected between the first inverter unit and the current source unit, for receiving a first data signal through its gate, and a second input terminal connected between the second inverter unit and the current source unit, for receiving a second data signal through its gate;
an equalization circuit unit for equalizing a potential of the first sensing node and a potential of the second sensing node according to a first control signal notifying an initial operation and a standby operation of the sense amplifier; and
first and second switching units for respectively switching the first sensing node and the first output terminal, and the second sensing node and the second output terminal according to a second control signal.

3. An amplifier according to claim 2, wherein the first and second input terminals comprise an NMOS transistor, respectively.

4. An amplifier according to claim 2, wherein the first and second inverter units comprise PMOS and NMOS transistors, respectively.

5. An amplifier according to claim 2, wherein the current source unit comprises an NMOS transistor.

6. An amplifier according to claim 2, wherein the first and second switching units comprise a transmission gate, respectively.

7. An amplifier according to claim 6, wherein the transmission gate comprises PMOS and NMOS transistors.

8. An amplifier according to claim 2, wherein the equalization circuit unit comprises a transmission gate.

9. An amplifier according to claim 8, wherein the transmission gate comprises PMOS and NMOS transistors.
